(19) United States
(12) Patent Application Publication
(10) Pub. No.: US 2006/0279274 A1
(43) Pub. Date: Dec. 14, 2006

(54) Sampling apparatus, and testing apparatus

(75) Inventor: Tsutomu Yamanaka, Tokyo (JP)

Correspondence Address: OSHA LIANG L.L.P., 1221 MCKINNEY STREET, SUITE 2800, HOUSTON, TX, 77010, US

(73) Assignee: Advantest Corporation, Tokyo (JP)

(21) Appl. No.: 11/387,445

(22) Filed: Mar. 23, 2006

(30) Foreign Application Priority Data
Mar. 23, 2005 (JP) 2005-084608

(51) Int. Cl. G01R 31/28

(52) U.S. Cl. 324/158.1

(57) ABSTRACT

Each channel comprises: an AD converter which converts a signal value of a corresponding input signal into a digital value in response to a received sampling clock; a counter which counts the pulses of the sampling clock; memory which sequentially stores the digital values at addresses corresponding to the counted values of the counter; a transmission/reception unit which outputs the counted value of the counter at a point in time at which acquisition of the waveform of the input signal is to be started in a case that the channel is set to be a main channel beforehand, and which receives the start data counted value from the main channel in a case that the channel is set to be a sub-channel; and an output unit which sequentially outputs the digital values stored in the memory with the digital value stored at the address corresponding to the start data counted value as the start data.

### CROSS REFERENCE TO RELATED APPLICATION

The present application claims priority from a Japanese Patent Application(s) No. 2005-084608 filed on Mar. 23, 2005, the contents of which are incorporated herein by reference.

### BACKGROUND OF THE INVENTION

1. Field of the Invention

The present invention relates a sampling device including multiple channels having a function of synchronously acquiring the waveforms of multiple input signals, and a test apparatus including the sampling device.

2. Related Art

Conventionally, test apparatuses for testing a tested device such as a semiconductor circuit or the like employ a sampling device having a function of acquiring the waveform of the signal output from the tested device. In some cases, the sampling device acquires signals output from multiple pins of the tested device, for example. In this case, in order to detect the relative phase of each signal, the sampling device needs to perform synchronous sampling of each signal.

FIG. 5 is a diagram which shows an example of a conventional sampling device 200. The sampling device 200 includes multiple channels 202-1 through 202-4 (which will be collectively referred to as “channels 202” hereafter). Each of the channels 202 receives a corresponding one of the signals output from the tested device. A particular channel from among the channels 202 is determined beforehand to be a main channel. The other channels serve as sub-channels which operate synchronously with the sampling of the main channel. With the present example, the channel 202-1 functions as a main channel. The other channels (202-2 through 202-4) function as sub-channels.

Each channel 202 receives a corresponding input signal, and performs sampling of the input signal in response to a sampling clock. Furthermore, the main channel 202-1 receives a trigger which is an instruction to start sampling. The main channel 202-1 distributes the trigger thus received to the other sub-channels 202. Each sub-channel 202 starts sampling in response to the trigger thus distributed. Such an arrangement provides synchronous sampling of multiple signals.

As of now, no prior art documents have been recognized, and accordingly description of prior art documents will be abbreviated here.

With the conventional sampling device 200, the trigger is transmitted from the main channel 202-1 to the sub-channels 202. Such an arrangement requires signal lines for transmitting the trigger. Let us consider an arrangement having a function of setting a desired channel from among the channels 202 to be a main channel. Such an arrangement requires a circuit configuration in which the signal lines are provided for transmission of the trigger between each of the channels 202 and the other channels 202 This means that each channel 202 requires signal lines for transmitting the trigger to all the other channels 202 and signal lines for receiving the trigger from all the other channels 202. Accordingly, such an arrangement having a function of setting a desired channel 202 to be a main channel requires a large number of signal lines.

Furthermore, such an arrangement in which the trigger is transmitted to all the channels 202 has a problem of skew occurring in the transmission paths. With such an arrangement, in order to accurately synchronize among the channels 202, there is a need to transmit a clock signal to each channel 202, as well as transmitting the trigger.

That is to say, each channel 202 receives the trigger and the clock signal. Then, each channel 202 synchronizes the trigger with the clock signal, thereby reducing deviation in the phase of the trigger arising from the skew. Such an arrangement further requires additional signal lines for the clock signals, leading to a further increase in signal lines.

### SUMMARY OF THE INVENTION

Accordingly, it is an object of the present invention to provide a sampling device and a test apparatus having a function of solving the aforementioned problems. This object is achieved by combining the features described in the independent claims in the Claims. Also, the dependent claims lay forth further advantageous specific examples of the present invention.

In order to solve the aforementioned problems, according to a first aspect of the present invention, a sampling device including multiple channels has a function of acquiring the waveforms of multiple input signals. With such an arrangement, each of the channels comprises: an AD converter which converts a signal value of a corresponding signal from among the input signals in response to a received sampling clock; a counter which counts the pulses of the sampling clock; memory which sequentially stores the digital values, which have been converted by the AD converter, at addresses corresponding to the counted values of the counter; a transmission/reception unit which outputs the counted value of the counter at a point in time at which acquisition of the waveform of the input signal is to be started in a case that the channel is set to be a main channel beforehand, and which receives the start data counted value from the main channel in a case that the channel is set to be a sub-channel; and an output unit which sequentially outputs the digital values stored in the memory with the digital value stored at the address corresponding to the start data counted value as the start data.

The counter of each of the channels may start to count the pulses of the sampling clock at the same time. Each of the channels may further comprise an initializing unit which synchronously initializes the counter thereof.

The sampling device may further comprise a control unit which controls a desired channel from among the multiple channels so as to function as a main channel, and which supplies a measurement trigger signal that instructs the main channel to start acquisition of the waveform of the input signal. With such an arrangement, the transmission/reception unit of the channel which has been controlled so as to function as the main channel may output the counted value of the counter to the control unit as the start data counted value at the time of reception of the measurement trigger signal. Furthermore, the control unit may transmit the start data counted value thus received to the transmission/reception units of the sub-channels.

The control unit may select two or more channels from among the multiple channels to be the main channels, and selects the sub-channels corresponding to each of the main channels, and may supply the start data counted value received from each of the main channels to the corresponding sub-channels.

An arrangement may be made in which, upon the counted value coming to be the end address of the memory, the counter resets the counted value thereof. Each of the memory may output the digital values stored therein from the start address corresponding to the start data counted value up to the end address obtained by adding together the start address and a sampling number set beforehand by a user. The number of addresses of each of the memory may be greater than the uppermost value of the sampling number which can be set by the user.

According to a second aspect of the present invention, a test apparatus for testing a tested device comprises: a signal supply unit which supplies a test signal to the tested device; a sampling device which synchronously acquires the waveforms of multiple signals output from the tested device; and a judging unit which determines the quality of the tested device based upon the waveform of each of the signals acquired by the sampling device. With such an arrangement, the sampling device includes multiple channels corresponding to the signals. Furthermore, each of the channels comprises: an AD converter which converts a signal value of the signal into a digital value in response to a received sampling clock; a counter which counts the pulses of the sampling clock; and memory which sequentially stores the digital values, which have been converted by the AD converter, at addresses corresponding to the counted values of the counter. With such an arrangement, a main channel, which has been selected beforehand from among the multiple channels, outputs the counted value of the counter as the first data counted value at the start time of acquisition of the waveform of the signal. On the other hand, the other channels, i.e., the sub-channels from among the multiple channels, receive the start data counted value output from the main channel. Then, the memory of each of the main channel and the sub-channels outputs the digital values stored therein at corresponding addresses, with the data stored at the address corresponding to the start data counted value as the first data thereof.

Note that the above outline of the invention is not a comprehensive list of all necessary features of the present invention, and that sub-combinations of these feature groups may also be inventions.

### BRIEF DESCRIPTION OF THE DRAWINGS

FIG. 1 is a diagram which shows an example of a configuration of a test apparatus 150 according to an embodiment of the present invention.

FIG. 2 is a diagram which shows an example of a configuration of a sampling device 100.

FIG. 3 is a diagram which shows another configuration of a channel 10.

FIG. 4 is a timing chart which shows an example of the operation of the sampling device 100.

FIG. 5 is a diagram which shows a conventional sampling device 200. Reference Numerals

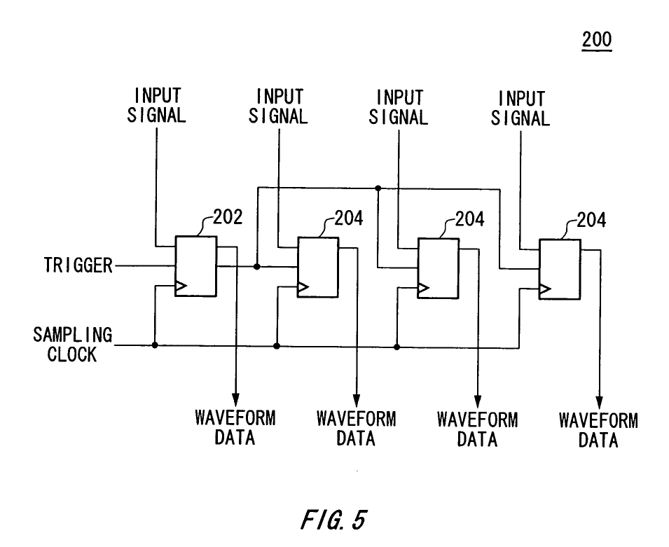

### DETAILED DESCRIPTION OF THE INVENTION

The present invention will now be described by way of embodiments; however, it should be understood that the following embodiments do not restrict the invention according to the Claims, and that combinations of features described in the embodiments are not necessarily indispensable to the present invention.

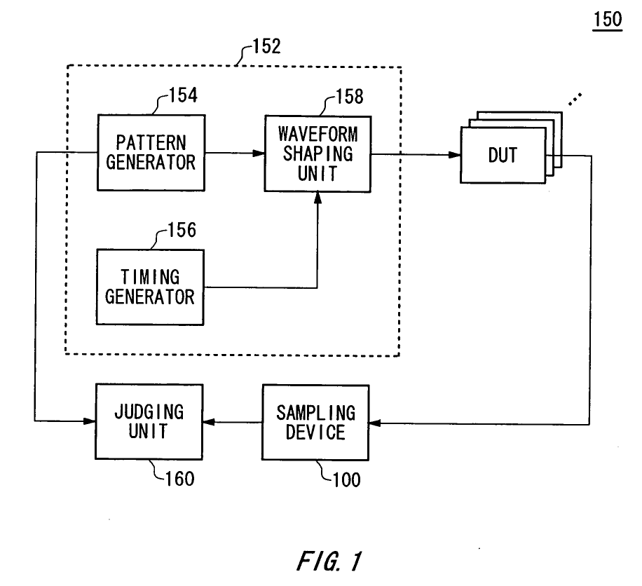

FIG. 1 is a diagram which shows an example of a configuration of a test apparatus 150 according to an embodiment of the present invention. The test apparatus 150 is an apparatus for testing a tested device 300 such as a semiconductor circuit or the like. The test apparatus 150 includes a signal supply unit 152, a sampling device 100, and a judging unit 160. The signal supply unit 152 supplies test signals to the tested device 300. The signal supply unit 152 according to the present example includes a pattern generator 154, a timing generator 156, and a waveform shaping unit 158.

The pattern generator 154 generates a test pattern for testing the tested device 300. The waveform shaping unit 158 generates a test signal based upon the test pattern. Specifically, the test pattern is a binary pattern formed of the digital values 1 and 0. The waveform shaping unit 158 generates a test signal which exhibits a voltage corresponding to each of the digital values of the test pattern according to the pulse of the received timing signal. The timing generator 156 generates a timing signal with a predetermined frequency, and supplies the timing signal to the waveform shaping unit 158. The waveform shaping unit 158 may generate multiple test signals to be supplied to the multiple pins of the tested device 300. Also, the waveform shaping unit 158 may generate multiple test signals to be supplied to the multiple tested devices 300.

The sampling device 100 synchronously acquires the waveforms of multiple signals output from the tested device 300. The aforementioned multiple signals may be signals output from the multiple pins of the tested device 300. Also, the aforementioned multiple signals may be signals output from the multiple tested devices 300.

The judging unit 160 determines the quality of the tested device 300 based upon each signal waveform acquired by the sampling device 100. The judging unit 160 may determine the quality of the tested device 300 based upon whether or not the expected signal supplied from the pattern generator 154 matches the signal waveform thus acquired, for example.

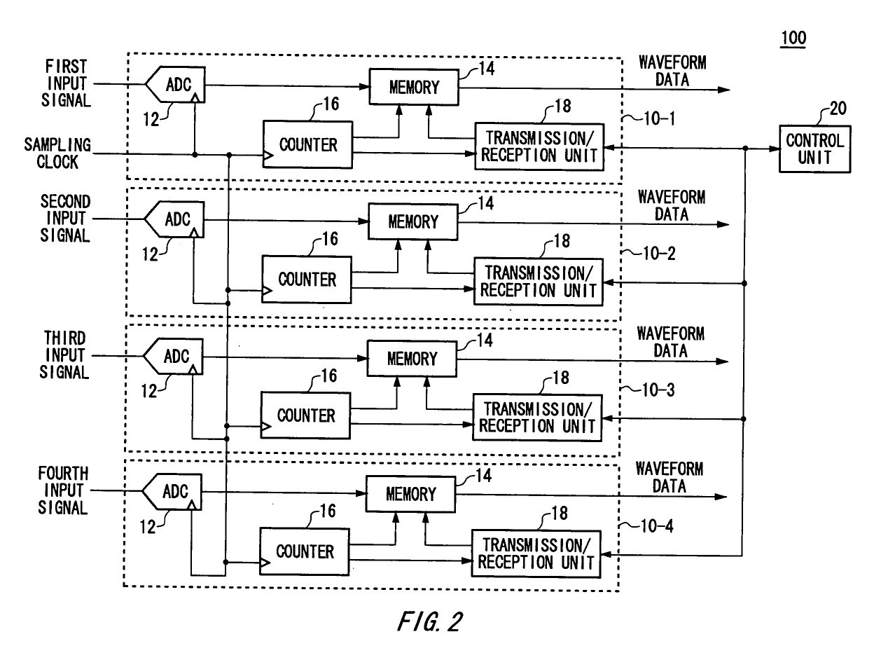

FIG. 2 is a diagram which shows an example of a configuration of the sampling device 100. The sampling device 100 includes multiple channels 10-1 through 10-4 (which will be collectively referred to as “channels 10” hereafter) provided corresponding to multiple input signals supplied from the tested device 300, and a control unit 20. While FIG. 2 shows the sampling device 100 including four channels 10, the number of the channels 10 included in the sampling device 100 is not restricted to such an arrangement.

The control unit 20 selects a particular channel 10 from the multiple channels 10 which is to function as a main channel. The control unit 20 instructs the selected cannel 10 to function as a main channel, and instructs the other channels 10 to function as sub-channels. Description will be made regarding a case in which the channel 10-1 functions as a main channel.

Each channel 10 has the same configuration, and includes an AD converter 12, memory 14, counter 16, and transmission/reception unit 18. The AD converter 12 receives a corresponding input signal, and converts the signal value of the input signal into a digital value according to the received sampling clock. The AD converter 12 of each channel 10 receives the same sampling clock.

The counter 16 counts the pulses of the sampling clock. The counter 16 of each of the channels 10 starts to count the pulses of the sampling clock, all at the same time. For example, each counter 16 may receive the same trigger which instructs the counter 16 to start to count the pulses at the same time. An arrangement may be made in which upon receiving the trigger, each counter 16 initializes the counted value. The aforementioned trigger may be received from the control unit 20.

The memory 14 sequentially stores the digital values, which have been sequentially converted by the AD converter 12, at addresses corresponding to the counted values of the counter 16. The AD converter 12 and the counter 16 each operate according to the sampling clock. Accordingly, the digital values sequentially converted by the AD converter 12 are sequentially stored in the memory 14 at different corresponding addresses.

With the present example, the memory 14 functions as ring memory. The ring memory is memory having a configuration in which data is sequentially overwritten from the start address after storage of data at the end address. With the present example, upon the counted value of the counter 16 matching the value corresponding to the end address of the memory 14, the counted value of the counter 16 is reset, thereby instructing the memory 14 to function as ring memory. With the present embodiment, the memory 14 functions as ring memory. With such an arrangement, the acquired digital values are sequentially stored while operating the AD converter 12 and the memory 14 according to a predetermined sequence, thereby acquiring counted values according to timings at which the waveform of the input signal is to be acquired. Furthermore, with such an arrangement, the data is output from the addresses corresponding to the aforementioned counted values after completion of the measurement, thereby enabling the waveform to be acquired at a desired timing. Upon each memory 14 storing the data corresponding to a predetermined number of addresses from the timing at which acquisition of the waveform is to be started, the storage of the data is stopped.

Let us consider a case in which the channel 10 is set beforehand to be a main channel. In this case, the transmission/reception unit 18 of this particular channel outputs a counted value of the counter 16 as the first data counted value at a point in time at which acquisition of the waveform of the input signal is to be started.

On the other hand, let us consider a case in which the channel 10 is set beforehand to be a sub-channel. In this case, the transmission/reception unit 18 of this channel receives the first data counted value output from the transmission/reception unit 18 of the main channel. The timing at which acquisition of the waveform of the input signal is to be started may be received from the control unit 20. With such an arrangement, the control unit 20 supplies a measurement trigger to the channel 10-1 so as to notify the channel 10-1 of the aforementioned timing. Subsequently, the transmission/reception unit 18 of the channel 10-1 outputs the counted value, which has been held at the time of reception of the measurement trigger, to the control unit 20 as the first data counted value. The control unit 20 transmits the first data counted value thus received to the transmission/reception units 18 of the other channels 10.

Each of the counters 16 starts to count the pulses at the same time. Accordingly, the counter 16 of each of the multiple channels 10 outputs the same counted value.

With such an arrangement, the channel 10-1, which is the main channel, transmits the counted value held at the start time of waveform acquisition, to the other channels 10. This enables each of the channels 10 to output data which represents the waveform of the input signal thereof at the same timing.

An output unit 19 sequentially outputs the digital values stored in the memory 14, with the digital value stored at the address corresponding to the first data counted value as the first data.

The output unit 19 may start to output the data upon reception of an output trigger which is an instruction to start the output of the data. Also, the output unit 19 may start the output the data after a predetermined period of time from reception of the measurement trigger.

The present embodiment provides the sampling device 100 having a simple configuration which enables the waveform data sets of multiple input signals to be acquired synchronously. Furthermore, such an arrangement allows a desired one of the multiple channels 10 to be selected as a main channel without involving a large number of signal lines.

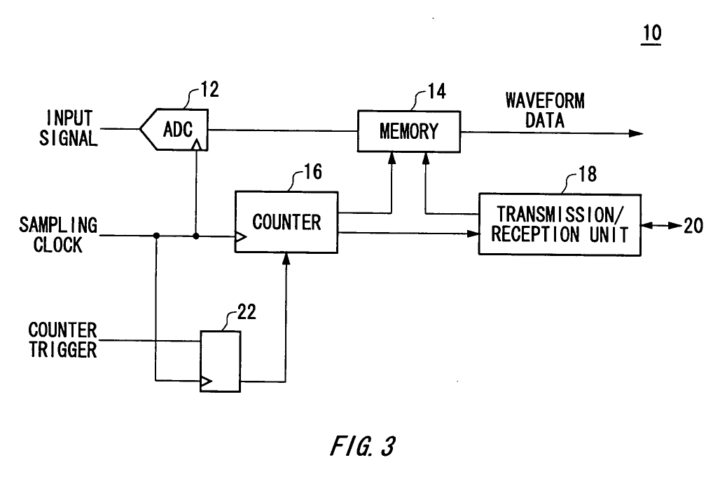

FIG. 3 is a diagram which shows another example of the configuration of the channel 10. The channel 10 according to the present example further includes an initializing unit 22, in addition to the configuration of the channel 10 described above with reference to FIG. 2. The initializing unit 22 initializes the corresponding counter 16 synchronously with the counters 16 of the other channels 10.

The initializing unit 22 of each channel 10 receives the same counter trigger. Then, the initializing unit 22 creates a signal by synchronizing the received counter trigger with the sampling clock, and initializing the counter 16 using the signal thus created.

Such an arrangement enables each of the counters 16 to be synchronously initialized without being affected by transmission skew in the counter trigger.

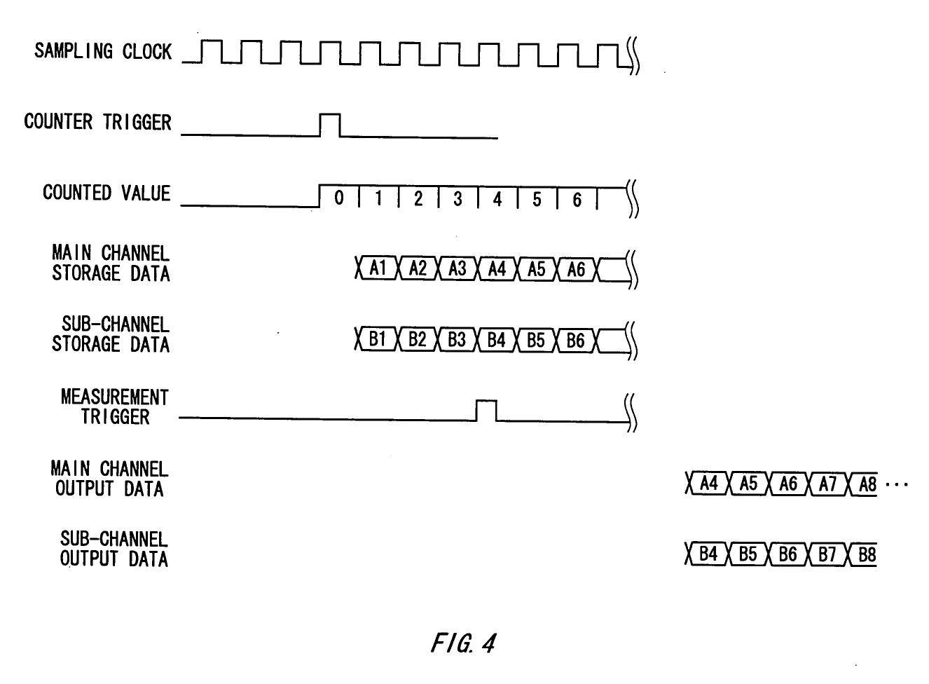

FIG. 4 is a timing chart which shows an example of the operation of the sampling device 100. The counted value of the counter 16 of each channel 10 is initialized by a counter trigger as shown in FIG. 4. Accordingly, each of the counters 16 synchronously outputs the same values.

Each memory 14 stores digital values, which have been sequentially acquired by the AD converter 12, at addresses corresponding to the counted values of the counter 16. Then, upon the channel 10-1, which functions as the main channel, receiving a measurement trigger, the channel 10-1 acquires the counted value of the counter 16, and transmits the counted value to the other channels 10 as the first data counted value. Subsequently, each channel 10 sequentially outputs data sets stored therein with the data stored at the address corresponding to the first data counted value as the first data. Such an operation allows the waveforms of multiple input signals to be synchronously acquired.

Also, the control unit 20 may select two or more main channels from the multiple channels 10. In this case, the control unit 20 selects the sub-channels corresponding to each main channel. Then, the control unit 20 receives the first data counted value from each main channel, and transmits the first data counted value to the sub-channels corresponding to this main channel. With such an arrangement, transmission of the first data counted values is performed via the control unit 20. This allows such transmission to be performed without involving signal lines for connecting the channels. As described above, with the sampling device 100 according to the present embodiment, a desired number of main channels can be selected as desired from the multiple channels 10.

Also, the period of time from reception of the measurement trigger up to the stop of data storage in the memory 14 may be determined according to a sampling number set beforehand by the user. Such an arrangement allows the user to set the sampling number according to which the waveform data of the input signal is to be acquired. With such an arrangement, each memory 14 stops data storage upon storage of data at a predetermined number of addresses following reception of the measurement trigger. Here, the number of the addresses corresponds to the aforementioned sampling number.

The aforementioned sampling number may be determined beforehand for each channel 10. With such an arrangement, each memory 14 outputs digital values, stored from the start address corresponding to the start data counted value up to the end address obtained by adding together the start address and the sampling number, as waveform data.

With such an arrangement, the number of addresses provided in each memory 14 is preferably greater than the uppermost value of the aforementioned sampling number which the user can be set. With such an arrangement, each memory 14 has a margin of available addresses. Thus, necessary data is not overwritten before the main channel transmits the first address counted value to the sub-channels.

While the present invention has been described above by way of embodiments, the technical scope of the present invention is not restricted to the description of the embodiments above. Various modifications and improvements can be made to the above embodiments, which can be clearly understood by those skilled in this art. It is clearly understood from the Claims that arrangements obtained by such modifications or improvements are also within the technical scope of the present invention. Industrial Applicability

As can be understood from the above description, the present invention offers a sampling device including multiple channels with a simple configuration which enables the waveform data of the multiple input signals to be synchronously acquired. Such an arrangement allows a desired channel from among multiple channels to be selected as a main channel without involving a large number of signal lines.

What is claimed is:

1. A sampling device including a plurality of channels having a function of acquiring the waveforms of a plurality of input signals, wherein
each of said channels comprises:
an AD converter which converts a signal value of a corresponding signal from among said input signals in response to a received sampling clock;
a counter which counts the pulses of said sampling clock;
memory which sequentially stores said digital values, which have been converted by said AD converter, at addresses corresponding to the counted values of said counter;
a transmission/reception unit which outputs said counted value of said counter at a point in time at which acquisition of the waveform of said input signal is to be started in a case that said channel is set to be a main channel beforehand, and which receives said start data counted value from said main channel in a case that said channel is set to be a sub-channel; and
an output unit which sequentially outputs said digital values stored in said memory with the digital value stored at the address corresponding to said start data counted value as the start data.

2. A sampling device according to claim 1, wherein said counter of each of said channels starts to count the pulses of said sampling clock at the same time.

3. A sampling device according to claim 2, wherein each of said channels further comprises an initializing unit which synchronously initializes said counter thereof.

4. A sampling device according to claim 1, further comprising a control unit which controls a desired channel from among said plurality of channels so as to function as a main channel, and which supplies a measurement trigger signal that instructs said main channel to start acquisition of the waveform of said input signal,
wherein said transmission/reception unit of said channel which has been controlled so as to function as said main channel outputs the counted value of said counter to said control unit as said start data counted value at the time of reception of said measurement trigger signal,
and wherein said control unit transmits said start data counted value thus received to said transmission/reception units of said sub-channels.

5. A sampling device according to claim 4, wherein said control unit selects two or more channels from among said plurality of channels to be said main channels, and selects said sub-channels corresponding to each of said main channels, and wherein said control unit supplies said start data counted value received from each of said main channels to said corresponding sub-channels.

6. A sampling device according to claim 1, wherein, upon said counted value coming to be the end address of said memory, said counter resets said counted value thereof.

7. A sampling device according to claim 1, wherein each of said memory outputs said digital values stored therein from the start address corresponding to said start data counted value up to the end address obtained by adding together said start address and a sampling number set beforehand by a user.

8. A sampling device according to claim 7, wherein the number of addresses of each of said memory is greater than the uppermost value of said sampling number which can be set by said user.

9. A test apparatus which tests a tested device, said test apparatus comprising:
a signal supply unit which supplies a test signal to said tested device;
a sampling device which synchronously acquires the waveforms of a plurality of signals output from said tested device; and
a judging unit which determines the quality of said tested device based upon the waveform of each of said signals acquired by said sampling device,
wherein said sampling device includes a plurality of channels corresponding to said signals,
and wherein each of said channels comprises
an AD converter which converts a signal value of said signal into a digital value in response to a received sampling clock,
a counter which counts the pulses of said sampling clock, and
memory which sequentially stores said digital values, which have been converted by said AD converter, at addresses corresponding to the counted values of said counter,
and wherein a main channel, which has been selected beforehand from among said plurality of channels, outputs the counted value of said counter as the first data counted value at the start time of acquisition of the waveform of said signal,
and wherein the other channels, i.e., the sub-channels from among said plurality of channels, receive said start data counted value output from said main channel,
and wherein said memory of each of said main channel and said sub-channels outputs said digital values stored therein at corresponding addresses, with the data stored at the address corresponding to said start data counted value as the start data thereof.
